(19) United States
(12) Patent Application Publication
(10) Pub. No.: US 2002/0047489 A1
(43) Pub. Date: Apr. 25, 2002

(54) Solid state energy generator

(76) Inventor: Gerrit Oudakker, Broek Op Langedijk (NL)

Correspondence Address: YOUNG & THOMPSON, 745 SOUTH 23RD STREET 2ND FLOOR, ARLINGTON, VA, 22202

(21) Appl. No.: 09/927,454

(22) Filed: Aug. 13, 2001

Related U.S. Application Data
(63) Continuation of application No. PCT/NL00/00092, filed on Feb. 13, 2000.

(30) Foreign Application Priority Data
Feb. 12, 1999 (NL) 1011294
Aug. 18, 1999 (NL) 1012851

(51) Int. Cl. H02N 3/00; H01L 35/30; H02N 10/00

(52) U.S. Cl. 310/306; 136/205

(57) ABSTRACT

Electrical energy generating system includes a generator being subject to a first temperature at a first location and a second temperature at a second location, the first temperature differing from the second temperature. The generator further includes a first and a second material, mutually differing galvanically, which are mutually connected in a galvanic conducting manner in two separated interface locations, such that they are connected in an electrical circuit to which an electricity consumer is connected, wherein the separated interface locations are at the first and second locations, such that the materials generate electricity by the Seebeck-Peltier-Thomson effect, supplying the electricity consumer.

The invention relates to a generator to convert thermal energy into electrical energy by using physical effects shown by particular solid state materials.

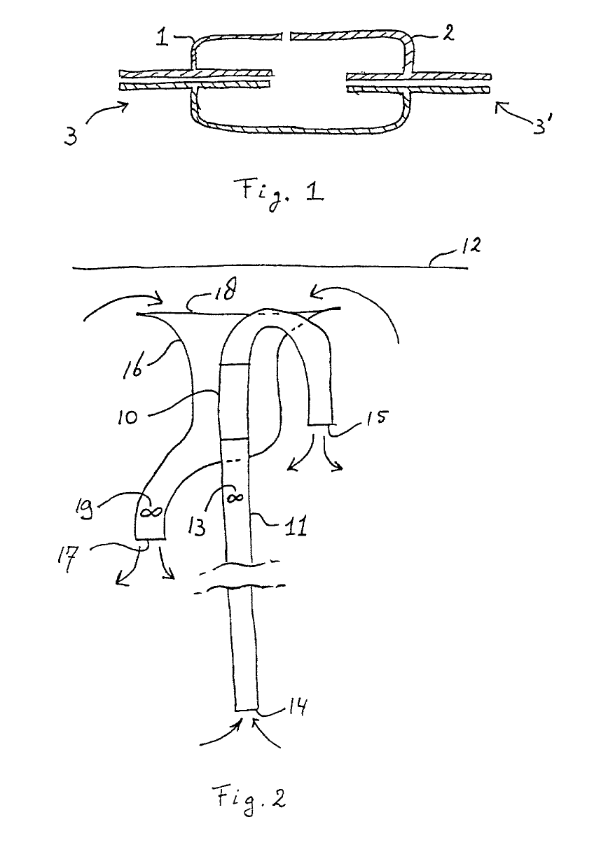

The Seebeck-Peltier-Thomson effect is generally known and is illustrated by FIG. 1, wherein an galvanic flow is generated if two different galvanic materials, such as metals like aluminium 1 and copper 2 are connected in circuit while at their connecting points 3 and 3′, different temperatures exist. The larger the surface area at the connecting points, the larger the galvanic flow. This effect is particularly useful in area's where the temperature differences are rather small, such as can be found in most natural environments, e.g. in deep water where the difference of the temperature at the surface and at a depth of e.g. 1500 m is about 20° C. Another field of application is solar energy, wherein solar energy is used to make the temperature difference, e.g. by converting it in warm water.

Up to now, nobody has succeeded in realising a commercial attractive generator based on the above effect. The object of the invention is to offer such a generator.

According to one aspect of the invention, two different galvanic materials are superimposed on top of a substrate, e.g. of plastic material, with the aid of a spray metalizing process, e.g. described in PCT/NL98/00507, such that they are galvanically interconnected. Such assembly is used as the connection point 3, 3′ referred to in FIG. 1. To protect such assembly from environmental attack, it is covered with preferably galvanic isolating material, such as plastic. In this way, the connecting points 3, 3′ (FIG. 1) can be made of very large surface area at low expenses. Such assemblies can easily be placed in a water body with temperature difference. To decrease its dimensions, such assembly can be folded or wrapped, as long as it is guaranteed that short circuiting is avoided. Such assembly can also be integrated in e.g. a road surface, e.g. below the top layer of asphalt concrete. This top layer will convert solar energy into thermal energy and heat the assembly. Another such assembly can be placed in a nearby water channel of lower temperature. Both assemblies connected in circuit generate a galvanic potential to be used to supply a power consumer, such as an electric lamp or an electromotor.

In a further aspect of the invention, the connecting points 3, 3′ (FIG. 1) are combined to provide a channel carrying a fluid having a temperature different from the temperature outside said channel. This offers a very attractive means, both from a constructive, fabrication, an application point of view.

In a further aspect of the invention, a thermal electical element is provided having two bodies of different materials with thermo-electrical properties, connected to a galvanic conductive member through a thermo-electrical neutral intermediate layer with high galvanic conductive properties and low thermal conductive properties. Such intermediate member can be of Strontium Titanaat as mono christal or in ceramic shape, possibly foamed en doted with Niobium. Thus, an important increase of efficiency can be provided. Without the intermediate member, the “figure of merit” Z is 3 to 5 to a maximum. With such intermediate member, Z can be e.g. 50.

The inventor has found out that, to obtain an efficiency allowing commercial success, the galvanic connection between the two connecting points 3, 3′ must provide the least galvanic resistance possible while at the same time providing the highest thermal resistance possible.

In the following, the invention, its further advantages and objects, is further explained with the aid of the enclosed drawing, showing non-limiting examples.

FIG. 1 shows a principle-sketch;

FIG. 2 shows a side view of an application;

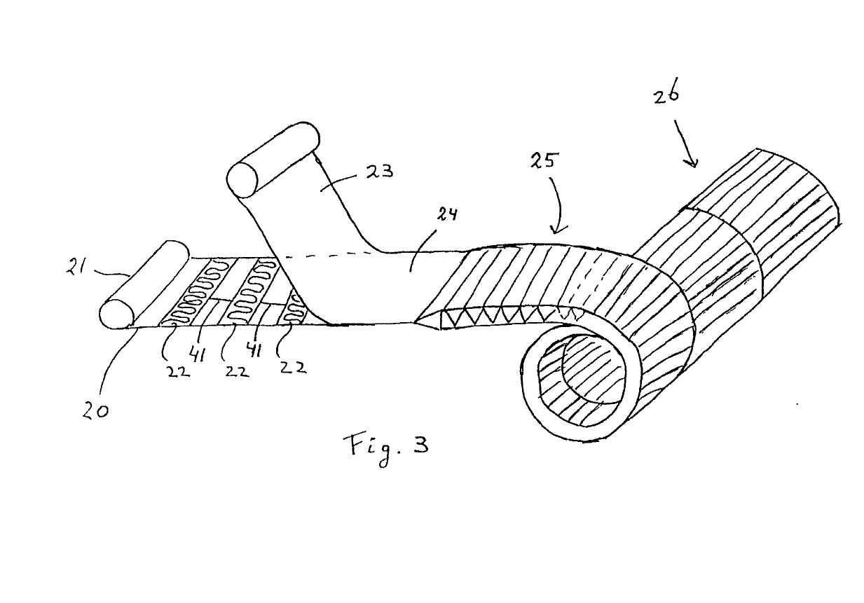

FIG. 3 shows a perspective view during production;

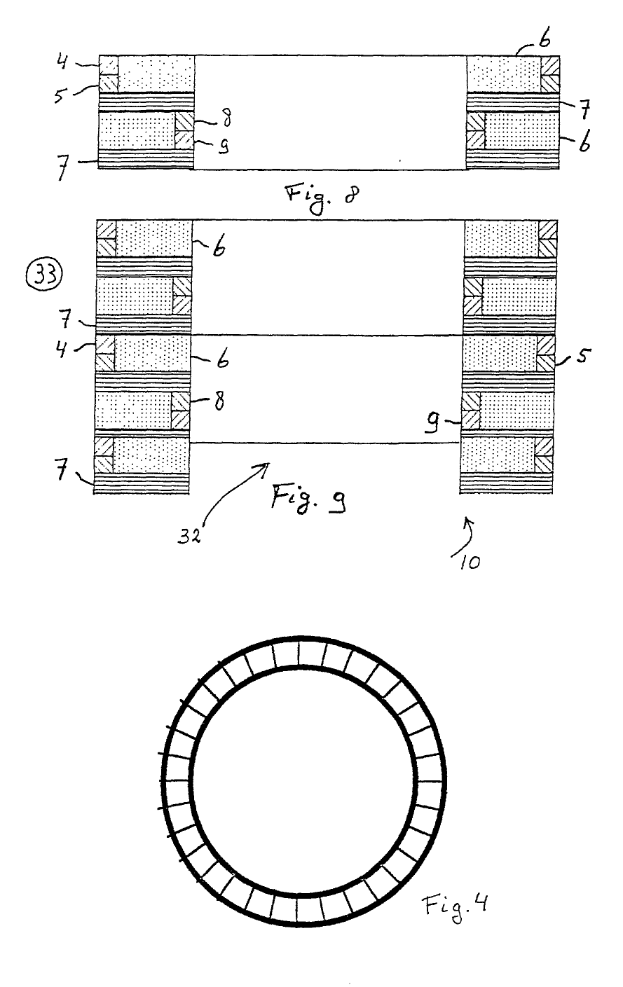

FIG. 4 shows a front view of a pipe of elements;

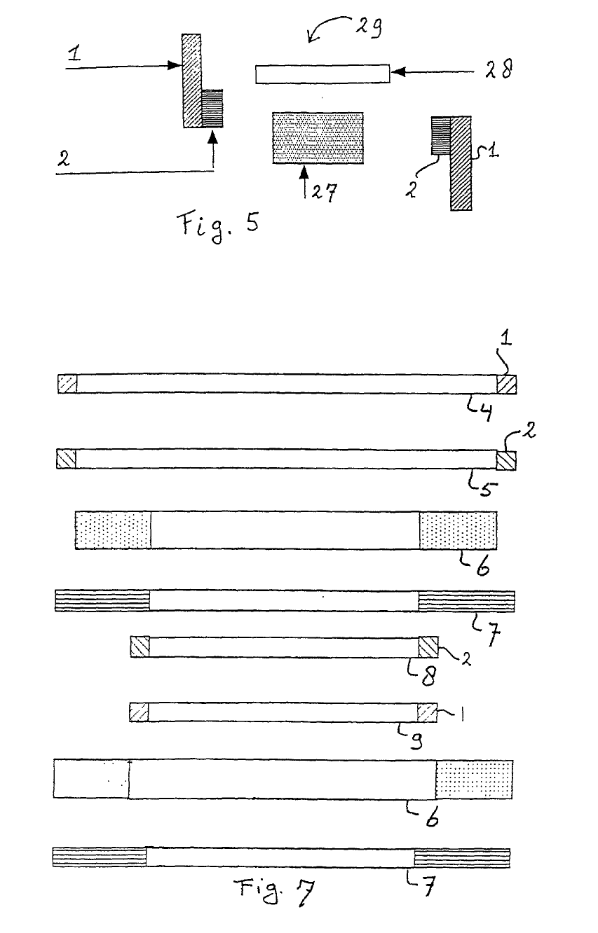

FIG. 5 shows an exploded view of a flat element;

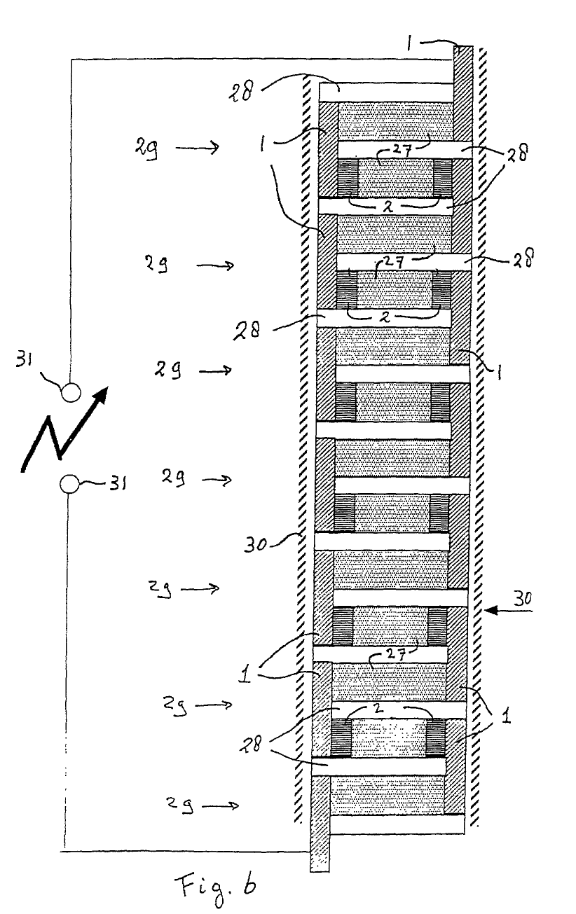

FIG. 6 shows a side view of an assembly of flat elements;

FIG. 7 shows an exploded view of a ring element;

FIG. 8 shows the ring element assembled in cross section;

FIG. 9 shows three ring elements assembled;

FIG. 10 shows another pipe assembly in side view;

FIG. 11 shows a detail of FIG. 10;

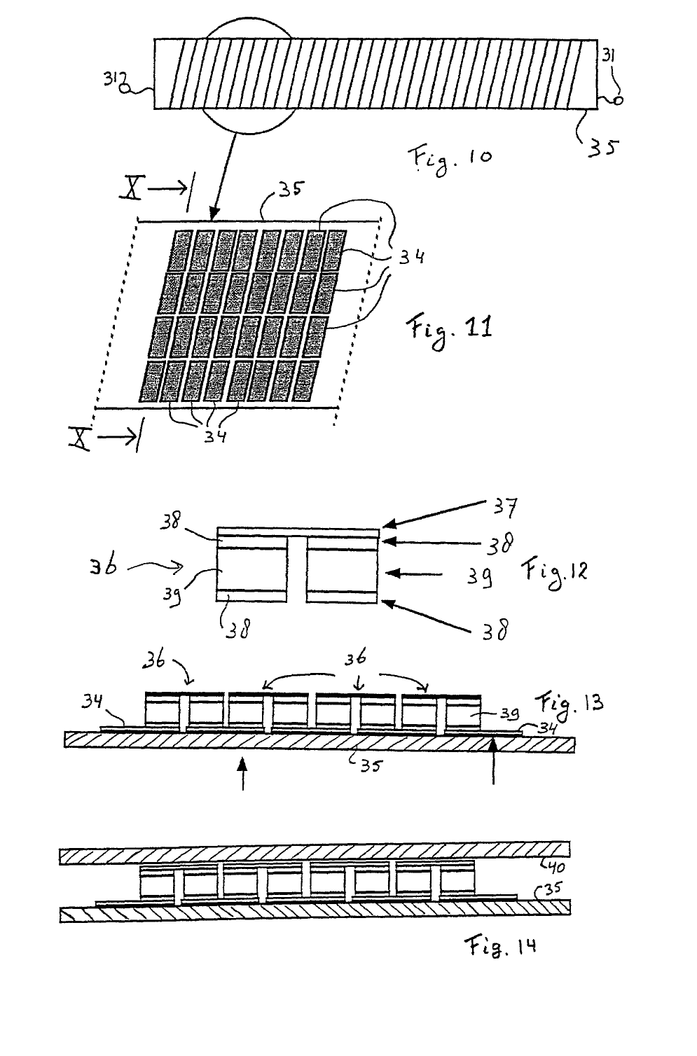

FIG. 12 shows a sub-element in side view;

FIG. 13 shows a subassembly of sub-elements; and

FIG. 14 shows the completed subassembly.

FIG. 2 shows a possible marine application, wherein the tube-like generator 10 is included in a line 11 extending to a depth where the water is substantially colder than at the surface 12, e.g. at a depth of some 1500 m. There, water is sucked in through a mouth piece 14 with the aid of a fluid propulsion means, here shown as a propellor 13 in the line 11. The comparatively cold water flows up through the generator 10 and leaves the line 11 at the mouth piece 15 comparatively close to the surface 12, e.g. within 10 m. therefrom. The generator 10 is surrounded by a sleeve 16 carrying comparatively warm water coming from near the surface 12, enetering the sleeve 16 through the mouth piece 18. The water flow through the sleeve 16 is generated by a fluid propulsion means, here shown as a propellor 19 in the sleeve 16. Due to the temperature difference between the inner and outer side of the generator 10, electrical power can be generated by using the Seebeck-Peltier-Thomson effect.

The generator 10 can be produced as shown in FIG. 3. On a galvanic isolating substrate, here a plastic sheet 21, coming from a stock 20, here shown as a roll, strips 22 are made, each comprising a layer of first galvanic material and a layer of second galvanic material on top, such that both layers mutually make intimite galvanic contact, providing the area's 3, 3′ (FIG. 1), e.g. made by spray metalizing. This subassembly is covered by a second galvanic isolating substrate, here a plastic sheet 23, coming from a stock. Then, this flat sheet 24 is wrinkeled such that each time the one strip 22 is at the top, the immediately succeeding strip 22 is at the bottom of the slab 25 thus created. This slab can be spirally wound into a tube 26. It is appreciated that the succeeding strips 22 should be conveniently galvanically interconnected by e.g. providing an electrical conductor 41 as shown.

An alternative way show FIGS. 5-9. FIG. 5 shows how an element 29 can be made of a first galvanic material 1 (e.g. iron; Fe), a second galvanic material 2 (e.g. nickel; Ni), a material 27, preferably powdery, with good electrical conductive properties and bad thermal conductive properties (e.g. a plastic, such as a polymer), preferably a material with an electrical conductivity comparable to copper, while at the same time having thermal insulating properties. Furthermore, an insulator 28 is used (electrical and preferably also thermally insulating).

The material 1 and/or 2 can also be of Bismuth Telluride (BiTel) or a mixture of two of more chosen from Fe, Ni, BiTel, or any other material to provide the Seebeck-Peltier-Thomson effect, or mixtures thereof.

FIG. 6 shows a sheet-type generator 10, composed of several elements 29 shown in FIG. 5, on both sides covered with a protective layer 30. At the left-hand side of the drawing, the temperature is lower than at the opposite side. Due to the Seebeck-Peltier-Thomson effect, a galvanic potential difference is created at the terminations 31.

FIGS. 7-9 show how a tube type generator 10 can be produced on the basis of the principle of FIG. 5. An outer ring 4 comprises the material 1 of FIG. 5; an outer ring 5 comprises the material 2 of FIG. 5; a ring 6 comprises the material 28 of FIG. 5; ring 7 comprises the material 27 of FIG. 5; an inner ring 8 comprises the material 2 of FIG. 5; the inner ring 9 comprises the material 1 of FIG. 5. Due to a temperature difference between the inner side 32 and the outer side 33, the Seebeck-Peltier-Thomson effect is obtained. FIG. 4 shows the end view of the tube of FIG. 9, viewed axially.

FIG. 10 shows a tube 35, preferably of ceramic material, covered with a spirally wound strip of seperate patches 34 of galvanic conductive material, preferably a metal layer, preferably copper, having a thickness of preferably approximately 200 microns. These patches 34 are preferably obtained by covering the tube 10 with a continuous layer and removing the material between de patches 34 (e.g. by laser cutting or chemical etching). On top of these patches 34, elements 36 are positioned as shown in FIG. 13. Each element 36 comprises a metal sheet 37, preferably of copper, four patches 38 providing the Seebeck-Peltier-Thomson effect, such as the material 1 of FIG. 5, and two blocks 39 of galvanic conducting and thermal isolating material, such as the material 27 of FIG. 5. The patches 38 can be such that all four of them are either of N-type or P-type thermoelectric material. In another embodiment, two are of N-type and two are of P-type thermoelectric material, wherein the one type is either at the side of the sheet 37, or at the opposite side (such that each block 39 has one of each type), or the one block 39 is only covered by the one type (e.g. N-type), the other block 39 is only covered by the other type (e.g. P-type) of thermoelectric material.

These elements 36 are galvanically connected to the patches 34 as shown in FIG. 13, which is a cross-sectional view along the line X-X in FIG. 11. Thus, each element 36 bridges two succeeding patches 34, viewed in the spiralling-direction of the patches 34 on the tube 35. Thus, a comparatively high voltage is created between leads 31 connected to the first and second patch 34, respectively.

An outer protective layer 40, e.g. of ceramics material, is finally provided (FIG. 14).

Further modifications and variants also belong to the invention, such as combination of one or more features of one of the above examples with one or more features of one or more of others of the above examples.

1. Electrical energy generating system applying the Seebeck-Peltier-Thomson effect, comprising a generator being subject to a first temperature at a first location and a second temperature at a second location, said first temperature differing from said second temperature, preferably differing at least 5° C., said generator further comprising a first and a second material, mutually differing galvanically, which are mutually connected in a galvanic conducting manner in two seperated interface locations, such that they are connected in an electrical circuit to which an electricity consumer is connected, wherein said separated interface locations are at said first and second locations, such that said materials generate electricity by the Seebeck-Peltier-Thomson effect, supplying said electricity consumer.

2. System according to claim 1, wherein said materials are selected from the group comprising iron (Fe), nickel (Ni), Bismuth Telluride, copper (Cu), aluminium (Al), niobium (No), metals.

3. System according to claim 1, wherein said generator comprises a plurality of elements, each comprising two opposite layers of said first material and a neigbouring layer of said second material, said opposing layers being mutually separated by a layer of thermally insulating, galvanically conductive third material (FIG. 9).

4. System according to claim 3, the one opposing layer also belonging to the succeeding element and the other opposing layer also belonging to the proceeding element, as viewed in the direction of flow of electricity through the galvanic circuit of elements (FIG. 6; FIG. 13).

5. System according to claim 3, wherein said third material comprises a polymer.

6 System according to claim 3, wherein the one opposing layer of first material is subjected to the first temperature and the other opposing layer of first material is subject to the second temperature.

7 System according to claim 3, wherein said opposing layers of first material are further seperated by a layer of thermally insulating, galvanically conductive fourth material, possibly the same as the third material, and seperated from said layer of third material.

8. System according to claim 1, wherein said generator is tube-like and the first temperature prevails within and the second temperature prevails outside it.

9. System according to claim 3, wherein said elements are provided in a spirally wound pattern.

10. System according to claim 3, wherein the elements are provided such that the galvanic circuit follows a serpentine path between the hot and cold side of the generator, said path being provided by said first and second and third and fourth materials.

11. System according to claim 3, wherein said layer of second material is positioned inward from said layer of first material (FIG. 6).

12. System according to claim 3, wherein between said third and said fourth material there is a galvanically isolating layer (28).

13. System according to claim 3, wherein the generator is located in a marine environment.

14. System according to claim 1, wherein the generator is made of a spirally wound slab of galvanically and preferably also thermally isolating wrinkled sheet containing cross-wise extending, mutually spaced strips, each containing a layer of first material on top of a layer of second material such that a first strip is at the top and an in the longitudinal direction of said sheet succeeding second strip is at the bottom side of said slab such that said strips are positioned in an alternating manner between said top and bottom side (FIG. 3).

15. System according to claim 1, wherein said first and second locations are at a comparatively small mutual distance.
